(19) United States
(12) Patent Application Publication
(10) Pub. No.: US 2013/0257329 A1
(43) Pub. Date: Oct. 3, 2013

(54) JUNCTION TEMPERATURE MEASUREMENT OF A POWER MOSFET

(71) Applicants: Christoph OROU, Schwaebisch Gmuend (DE); Stefan Walz, Schwaebisch Gmuend (DE)

(72) Inventors: Christoph OROU, Schwaebisch Gmuend (DE); Stefan Walz, Schwaebisch Gmuend (DE)

(21) Appl. No.: 13/772,869

(22) Filed: Feb. 21, 2013

(30) Foreign Application Priority Data
Mar. 30, 2012 (DE) 10 2012 102 788.9

(51) Int. Cl. H01L 23/34; H02P 27/06

(52) U.S. Cl. CPC H01L 23/34; H02P 27/06
USPC 318/400.26; 257/48; 324/71.1

(57) ABSTRACT

A component used as a circuit breaker for a power inverter for actuating a drive motor of a steering support system of a vehicle comprises a MOSFET having a gate, a drain and a source, and a first diode having an anode and a cathode, wherein the diode is provided for measuring the junction temperature of the MOSFET, and wherein the MOSFET is of the n-channel type or p-channel type, and the source is connected to the cathode.

### FIELD OF THE INVENTION

The present invention relates to a component used as a circuit breaker for a power inverter for actuating a drive motor of a steering support system of a vehicle, to a power-assisted steering mechanism for a motor vehicle, and to a steering system.

### BACKGROUND OF THE INVENTION

Components are known from prior art that comprises a MOSFET as well as a diode for measuring the junction temperature of the MOSFET. The diode comprises an anode terminal and a cathode terminal, which are designed so that they lead out of the component.

### SUMMARY OF THE INVENTION

Components from the prior art, which make a measurement of the junction temperature of the MOSFET possible, comprise at least two terminals of an additional sensor diode. The two additional terminals require an additional circuit, which leads to an increased cost in the manufacturing and an increased space requirement for the circuit and the die area (chip area) of the MOSFET.

Thus, one object is to provide a component having a MOSFET, which allows for measurement of the junction temperature of the MOSFET, wherein the fewest possible additional terminals are needed, or wherein the additional wiring can be minimized or the space requirement for the circuit and for the die surface do not have to be significantly increased or modified.

As a first embodiment of the invention, a component is provided as a circuit breaker for a power inverter for actuating a drive motor of the steering support system of a vehicle, comprising a MOSFET having a gate, a drain and a source, and a first diode having an anode and a cathode, wherein the diode is provided for measuring the junction temperature of the MOSFET, wherein the MOSFET is of an n-channel type or a p-channel type, and the source is connected to the cathode.

The component according to the invention can advantageously achieve optimal utilization of the thermal capabilities of the component, more particularly due to the fact that, by virtue of the component according to the invention, it is possible to reduce the power to the steering support system, if the component detects an upper temperature limit for the MOSFET. This allows the complete potential of the MOSFET in the power inverter to be exploited.

According to the invention, the source of the MOSFET and the cathode of the diode are connected with one another, whereby the number of terminals leading out of the chip can be reduced.

In a second embodiment of the invention, a power-assisted steering mechanism for a motor vehicle is provided, comprising a drive motor for generating a drive torque on a steering rack of a steering system and a power inverter for actuating the drive motor, wherein the power inverter comprises a component and/or six components.

Through the use of at least one component according to the invention, a power-assisted steering mechanism can be provided, which makes less elaborate circuitry necessary, and which therefore requires less installation space as compared to power-assisted steering mechanisms known from the prior art.

In a third embodiment of the invention, a steering system comprising a power-assisted steering mechanism is provided.

In a fourth embodiment of the invention, a method for measuring the junction temperature of a MOSFET of a component is provided, comprising the steps of: feeding a constant forward current I_{F} into the diode; and measuring the forward voltage V_{F} of the diode.

In a fifth embodiment of the invention, a method for measuring the junction temperature of a MOSFET of a component is provided, comprising the steps of: maintaining the forward voltage V_{F} of the diode constant; and measuring the forward current I_{F} of the diode.

With a component according to the invention, the sensor diode/diode can be connected in essentially two different ways in order to be able to determine the junction temperature of the corresponding MOSFET. On one hand, a constant current can be fed into the diode in the conducting direction and the temperature-dependent voltage of the diode can be measured. On the other hand, conducting-state voltage of the diode can be maintained constant and the diode current can be measured and the junction temperature thereby determined.

In accordance with an exemplary embodiment of the invention, a component is provided, wherein the first diode and the MOSFET are disposed on the same semiconductor substrate.

Very good thermal contact is achieved between the diode and the barrier layer of the MOSFET by arranging the diode and of the MOSFET on the same semiconductor substrate. This allows for direct temperature measurement, resulting in precise data regarding the junction temperature.

In a further embodiment of the invention, a component is provided, wherein the first diode is designed as a silicon diode, suppressor diode, Schottky diode, PIN diode or Zener diode.

Cost-effective design of the component according to the invention is achieved through the use of standard types of diodes, for example a silicon diode, suppressor diode, Schottky diode, PIN diode or Zener diode.

According to a further embodiment of the present invention, a component is provided, wherein the component comprises a second diode and/or a third diode and/or a fourth diode and/or any number of additional diodes, wherein the first diode and/or the second diode and/or the third diode and/or the fourth diode, and/or any number of diodes are connected in series and/or thermally coupled to the barrier layer of the MOSFET.

The temperature of the barrier layer can be measured more precisely through the use of multiple diodes, which are connected in series, since this allows the phenomenon of the temperature dependency of the corresponding forward voltages to be used repeatedly.

Providing a component with a MOSFET that comprises a diode on-board for measuring the junction temperature can be regarded as a concept of the invention. The cathode of the diode is internally connected to the source of the MOSFET, whereby the number of terminals leading out can be reduced. This not only allows for precise measurement of the junction temperature, but also makes it possible to reduce the chip area for the component.

As a matter of course, the individual characteristics can also be combined with one other, which also allows other advantageous effects to develop that go beyond the sum of the individual effects.

Further details and advantages of the invention will become apparent from the embodiments illustrated in the drawings.

### BRIEF DESCRIPTION OF THE DRAWINGS

FIG. 1 is a circuit diagram of an inverter comprising six components according to the invention for a drive motor of a power-assisted steering mechanism;

FIG. 2 is a circuit diagram of a component according to the invention having an n-channel type MOSFET;

FIG. 3 is a graph of voltage characteristics of a diode at different constant currents;

FIG. 4 is a circuit diagram of a component according to the invention having a p-channel type MOSFET; and

FIG. 5 is a component according to the invention having external wiring for measuring the junction temperature of a MOSFET.

### DETAILED DESCRIPTION OF THE PREFERRED EMBODIMENTS

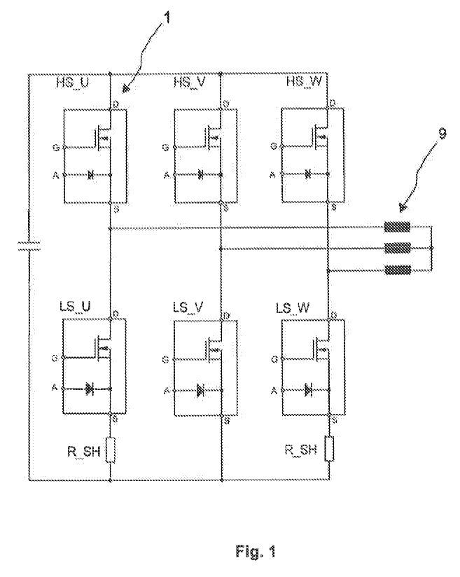

FIG. 1 shows an inverter circuit having six components 1 according to the invention for actuating a drive motor 9 of a power-assisted steering mechanism (EPS power inverter). The components 1 according to the invention each comprise a sensor diode/diode for measuring the junction temperature. The junction temperature is the most important quantity to be limited in a circuit breaker, such as a MOSFET, power MOSFET or high performance MOSFET. The junction temperature must not be exceeded, or continuously exceeded, during operation. Otherwise there is a risk of a thermal event in the component and the component will no longer function correctly, or may fail completely. The failure of one or more of the MOSFETs of an EPS power inverter can lead to the steering of the vehicle in question being blocked. Measuring the current junction temperature is therefore advantageous, in order to allow the performance potential of the EPS power inverter in question to be fully exploited on one hand, and to be able to reliably prevent the steering from being blocked on the other hand.

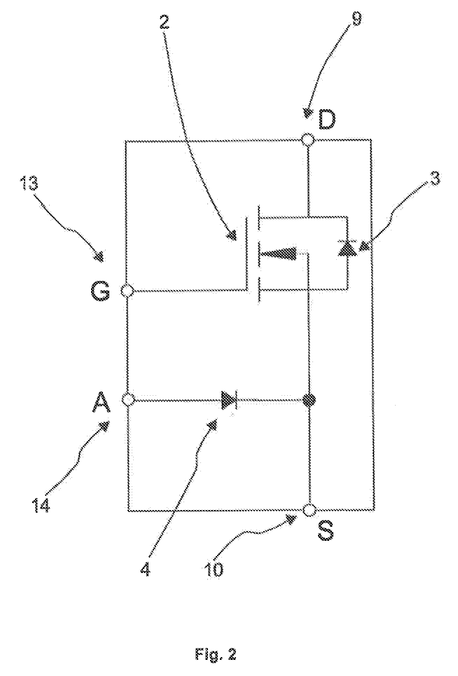

FIG. 2 shows a component according to the invention having an n-channel type MOSFET 2, which comprises a drain terminal 9, a source terminal 10 and a gate terminal 13. The component comprises a diode 4, which is in very good thermal contact with the barrier layer of the MOSFET 2. The cathode of the diode 4 is connected within the component to the source terminal 10 of the component whereby, advantageously only one terminal of the diode 4 must lead out of the component instead of both terminals, as is the case in components known from the prior art.

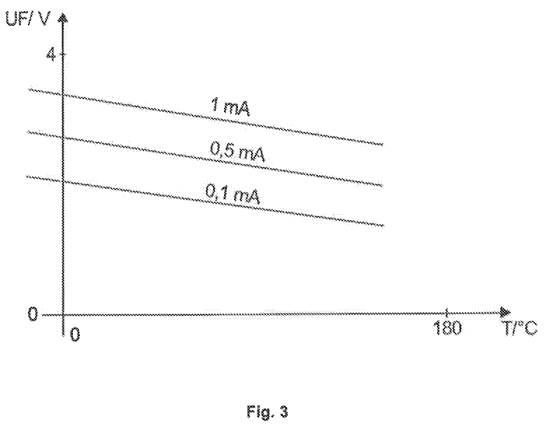

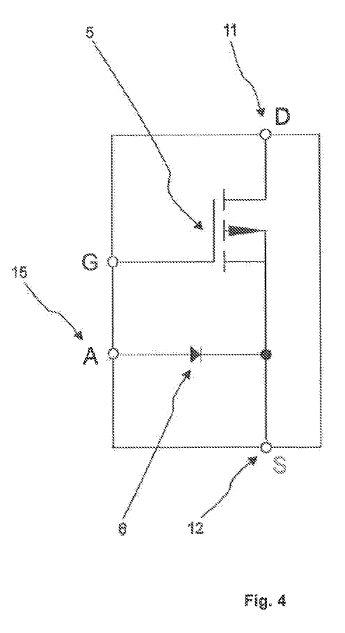

FIG. 3 shows a family of characteristic curves, which represent the conducting-state voltages/forward voltages U_{F}, which drop across a diode with respect to the temperature in degrees Celsius. This results in parallel displacement of the characteristic curves depending upon the parameter of the forward current, which is maintained constant. The phenomenon of the temperature dependency of the forward voltage is exploited for measuring the MOSFET temperature. In the case of a silicon diode (SI diode), for example, a change in the forward voltage ΔV_{F} of approximately −2 mV/K is to be expected as a function of the temperature. A constant current must flow through the diode in a forward direction in order to be able to use the temperature-dependent effect of the forward voltage. In so doing, it should be noted that the current flowing in the forward direction is small enough that the MOSFET temperature is not affected by the power loss that is caused by the diode current itself. In the case of the embodiments in FIGS. 2 and 4, a constant diode current I_{F} can be generated with a high-precision current source and fed via the anode terminal 14 or 15 that is led out.

FIG. 4 shows a component having a p-channel type MOSFET 5. The junction temperature of the MOSFET 5 can be determined according to the invention by arranging a diode 6 in a manner that is analogous to the embodiment in FIG. 2, wherein the cathode of the diode 6 is connected to the source terminal 12 of the MOSFET 5, and the anode terminal 15 of the diode 6 is designed so that it leads out of the component.

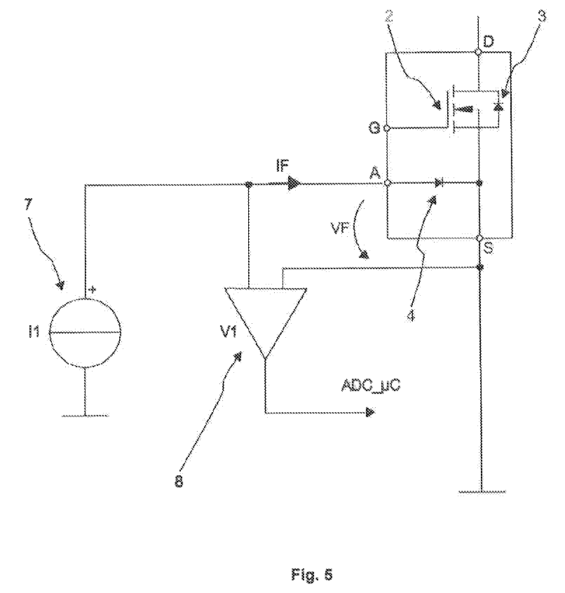

FIG. 5 shows a circuit of a component for junction temperature measurement according to the invention having a MOSFET 2 according to the embodiment in FIG. 2, having a led-out drain terminal, a source terminal and a gate terminal. The component comprises a diode 4 on-board, wherein the cathode of the diode 4 is connected to the source terminal of the MOSFET. The diode 4 is thermally coupled to the barrier layer of the MOSFET 2, whereby direct measurement of the junction temperature of the MOSFET 2 is made possible. This measurement allows thermally critical operating states of the MOSFET 2 to be determined and countermeasures to be initiated if necessary, in particular switching off the MOSFET 2. In order to determine the junction temperature of the MOSFET 2, a current I_{F} is used, with which the diode 4 is operated in the forward direction. The current I_{F} is generated by the current source 7. As a result of the current flow I_{F} through the diode 4, a forward voltage V_{F} drops across the diode 4, which is temperature-dependent in accordance with the relationship V_{F}=f(I_{F}=const, T). This voltage V_{F} can be measured between the anode of the diode 4 and the source terminal of the MOSFET 2. After analog signal processing, the voltage V_{F} can be provided in digitized form for further processing by means of an amplifier circuit 8 and subsequent AD conversion.

The temperature information thus determined can be used to protect the MOSFETs from thermal overload, for example. If, for example, a critical junction temperature is reached, the steering support for the vehicle is reduced and therefore the power loss that occurs in the power inverter-MOSFETs is decreased. In a further possible application, a temperature current model could be derived from the directly measured MOSFET junction temperatures, which could be used to estimate the current motor phase currents. This has the advantage that the sensors for the phase current measurement can be dispensed with.

The auxiliary circuit for applying the constant current I_{F}, which is to say in particular the constant current source 7, and the signal processing circuit for the measured value, in particular the amplifier circuit 8 and the AD conversion, can be designed as a direct circuit or integrated into the output stage driver or into the MOSFET itself as a circuit block.

The advantage to the MOSFET temperature measurement results from the precision of the measured temperature values, which are directly related to the junction temperature of the MOSFET. Thus there is no longer a need for complex thermal models from which the MOSFET temperature must be derived, for example from an NTC sensor temperature. Such an NTC sensor for determining the output stage temperature can thus be eliminated and the cost saved.

As a further variant, it is conceivable that the voltage V_{F} is maintained constant and the current I_{F} in is measured as a function of the junction temperature. In this variant, however it must be taken into consideration that the forward current I_{F} is very small. A current I_{F} thus received could be amplified with the aid of a current mirror and measured as a voltage on an instrument shunt. The voltage drop across the instrument shunt would then correspond to the junction temperature of the power MOSFET.

It should be noted that the term “comprise” does not preclude additional elements or method steps, and likewise the terms “a” and “an” do not preclude multiple elements and steps.

The reference numerals used merely serve to increase comprehensibility and should in no way be considered as limiting, the scope of protection of the invention being set forth in the claims.

### LIST OF REFERENCE NUMERALS

1 Component

2 MOSFET

3 Flyback diode

4 Diode

5 MOSFET

6 Diode

7 Constant current source

8 Amplifier circuit

9 Drive motor of a servo circuit

10 Source terminal

11 Drain terminal

12 Source terminal

13 Gate terminal

14 Anode terminal

15 Anode terminal

1. A component used as a circuit breaker for a power inverter for actuating a drive motor of the steering support system of a vehicle, comprising:
a MOSFET having a gate, a drain and a source, and
a first diode having an anode and a cathode, wherein the diode is provided for measuring the junction temperature of the MOSFET, and wherein
the MOSFET is of the n-channel type or p-channel type, and the source is connected to the cathode.

2. The component according to claim 1, wherein the first diode and the MOSFET are disposed on the same semiconductor substrate.

3. The component according to claim 1, wherein the first diode is designed as a silicon diode, a suppressor diode, a Schottky diode, a PIN diode or a Zener diode.

4. A component according to claim 1, wherein the component comprises a second diode and/or a third diode and/or a fourth diode and/or any number of additional diodes, wherein the first diode and/or the second diode and/or the third diode and/or the fourth diode and/or any number of additional diodes are connected in series and/or are thermally coupled to the barrier layer of the MOSFET.

5. A power-assisted steering mechanism for a motor vehicle, comprising:
a drive motor for generating a drive torque on a steering rack of a steering system;
and
a power inverter for actuating the drive motor,
wherein
the power inverter comprises a component and/or six components according to claim 1.

6. A steering system comprising a power-assisted steering mechanism according to claim 5.

7. A method for measuring the junction temperature of a MOSFET of a component according to claim 1, comprising the steps of:
feeding a constant forward current I_{F} into the diode; and
measuring the forward voltage V_{F} of the diode.

8. A method for measuring the junction temperature of a MOSFET of a component according to claim 1, comprising the steps of:
maintaining the forward voltage V_{F} the diode constant; and
measuring the forward current I_{F} of the diode.
